(19) United States
(12) Patent Application Publication
(10) Pub. No.: US 2024/0204731 A1
(43) Pub. Date: Jun. 20, 2024

(54) DOHERTY AMPLIFIER

(71) Applicant: Mitsubishi Electric Corporation, Tokyo (JP)

(72) Inventors: Shuichi SAKATA, Tokyo (JP); Marie TAGUCHI, Tokyo (JP); Yuji KOMATSUZAKI, Tokyo (JP)

(73) Assignee: Mitsubishi Electric Corporation, Tokyo (JP)

(21) Appl. No.: 18/595,818

(22) Filed: Mar. 5, 2024

Related U.S. Application Data
(63) Continuation of application No. PCT/JP2021/042707, filed on Nov. 22, 2021.

(51) Int. Cl. H03F 1/02; H03F 1/56; H03F 3/21

(52) U.S. Cl. CPC H03F 1/0288; H03F 1/56; H03F 3/211; H03F 2200/423; H03F 2200/48; H03F 2203/21139

(57) ABSTRACT

A Doherty amplifier including: a first transistor for main amplifier having a source-to-drain parasitic capacitance and operating in class AB; a transmission line whose input end is connected to an output end of the first transistor and whose output end is connected to a composite point; a second transistor for auxiliary amplifier having a source-to-drain parasitic capacitance and operating in class C; a series capacitor whose input end is connected to an output end of the second transistor and whose output end is connected to the composite point, and to reduce the capacitance value of impedance seen from the composite point toward the output end of the second transistor at the time of a backoff operation; and an output matching circuit connected between the composite point and a point of connection to an output load, to match the impedance of the composite point to the impedance of the output load.

### CROSS REFERENCE TO RELATED APPLICATIONS

This application is a Continuation of PCT International Application No. PCT/JP2021/042707, filed on Nov. 22, 2021, which is hereby expressly incorporated by reference into the present application.

### TECHNICAL FIELD

The present disclosure relates to a Doherty amplifier in which a transistor for main amplifier operating in class AB and a transistor for auxiliary amplifier operating in class C are connected in parallel.

### BACKGROUND ART

In recent years, in order to provide an improvement in the transmission speed in wireless communication systems like those for mobile phones, signals having a large peak to average power ratio (referred to as PAPR hereinafter) are used.

It has been desired that a signal having a large PAPR can be amplified with a high degree of efficiency, and a Doherty amplifier is proposed in Patent Literature 1 as an amplifier which amplifies a signal for communications with a high degree of efficiency.

In the Doherty amplifier disclosed in Patent Literature 1, a main amplifier operating in class AB or class B and a peak amplifier operating in class C are connected in parallel, and the source-to-drain parasitic capacitance of a transistor chip which constitutes the main amplifier, the source-to-drain parasitic capacitance of a transistor chip which constitutes the peak amplifier, a transmission line whose other end is connected to an output terminal, and a bonding wire which connects the drain pad of the transistor chip which constitutes the peak amplifier and an end of the transmission line equivalently constitute a 90-degree delay circuit.

### CITATION LIST

### Patent Literature

Patent Literature 1: Japanese Patent No. 6773256

### SUMMARY OF INVENTION

### Technical Problem

However, it is desired to increase the backoff amount of the output circuit of the Doherty amplifier which uses the parasitic capacitance of the transistor for main amplifier and the parasitic capacitance of the transistor for auxiliary amplifier, and to make a further improvement in the efficiency to signals having a large PAPR.

The present disclosure is made in view of the above-mentioned point, and it is an object of the present disclosure to provide a Doherty amplifier that can implement high-efficiency amplification on a signal having a large PAPR.

### Solution to Problem

A Doherty amplifier according to the present disclosure includes: a transistor for main amplifier having a source-to-drain parasitic capacitance and operating in class AB; a transmission line whose input end is connected to an output end of the transistor for main amplifier and whose output end is connected to a composite point; a transistor for auxiliary amplifier having a source-to-drain parasitic capacitance and operating in class C; a series capacitor whose input end is connected to an output end of the transistor for auxiliary amplifier and whose output end is connected to the composite point, and to reduce a capacitance value of impedance seen from the composite point toward the output end of the transistor for auxiliary amplifier at a time of a backoff operation; and an output matching circuit connected between the composite point and a point of connection to an output load, and to match impedance at the composite point to impedance of the output load.

### Advantageous Effects of Invention

According to the present disclosure, while matching between the impedance at the current source of the transistor for main amplifier and the impedance at the current source of the transistor for auxiliary amplifier at the time of the saturated operation can be satisfied, the backoff amount at which an efficiency peak point appears can be increased and high-efficiency amplification can be implemented on a signal having a large PAPR at the time of the backoff operation.

### BRIEF DESCRIPTION OF DRAWINGS

FIG. 1 is a circuit configuration diagram showing an output circuit of a Doherty amplifier according to Embodiment 1;

FIG. 2 is a circuit configuration diagram showing an equivalent circuit of the output circuit of the Doherty amplifier according to Embodiment 1;

FIG. 3 is an equivalent circuit configuration diagram at the time of a backoff operation in the output circuit of the Doherty amplifier according to Embodiment 1;

FIG. 4 is an equivalent circuit diagram for explaining the principle of operation at the time of the backoff operation in the output circuit of the Doherty amplifier according to Embodiment 1;

FIG. 5 is a view simply showing the locus of an impedance transformation from a composite point to a current source of a transistor for main amplifier in a Smith chart at the time of the backoff operation in the output circuit of the Doherty amplifier according to Embodiment 1;

FIG. 6 is a view showing in detail the locus of the impedance transformation from the composite point to the current source of the transistor for main amplifier in the Smith chart at the time of the backoff operation in the output circuit of the Doherty amplifier according to Embodiment 1;

FIG. 7 is an equivalent circuit configuration diagram at the time of a saturated operation in the output circuit of the Doherty amplifier according to Embodiment 1;

FIG. 8 is a view showing the locus of an impedance transformation from the composite point to the current source of the transistor for main amplifier in a Smith chart at the time of the saturated operation in the output circuit of the Doherty amplifier according to Embodiment 1;

FIG. 9 is a view showing the locus of an impedance transformation from the composite point to a current source of a transistor for auxiliary amplifier in the Smith chart at the time of the saturated operation in the output circuit of the Doherty amplifier according to Embodiment 1;

FIG. 10 is a circuit configuration diagram showing an equivalent circuit of an output circuit of a Doherty amplifier according to a reference example;

FIG. 11 is an equivalent circuit configuration diagram at the time of a backoff operation in the output circuit of the Doherty amplifier according to the reference example;

FIG. 12 is an equivalent circuit diagram for explaining the principle of operation at the time of the backoff operation in the output circuit of the Doherty amplifier according to the reference example;

FIG. 13 is a view simply showing the locus of an impedance transformation from a composite point to a current source of a transistor for main amplifier in a Smith chart at the time of the backoff operation in the output circuit of the Doherty amplifier according to the reference example;

FIG. 14 is an equivalent circuit configuration diagram at the time of a saturated operation in the output circuit of the Doherty amplifier according to the reference example;

FIG. 15 is an equivalent circuit diagram for explaining the principle of operation at the time of the saturated operation in the output circuit of the Doherty amplifier according to the reference example;

FIG. 16 is a view simply showing the locus of an impedance transformation from the composite point to the current source of the transistor for main amplifier in a Smith chart at the time of the saturated operation in the output circuit of the Doherty amplifier according to the reference example;

FIG. 17 is a view showing a specific example of computation of the drain efficiency of the transistor for main amplifier with respect to a backoff amount at the time of the backoff operation; and

FIG. 18 is a circuit configuration diagram showing an output circuit of a Doherty amplifier according to Embodiment 2.

### DESCRIPTION OF EMBODIMENTS

### Embodiment 1

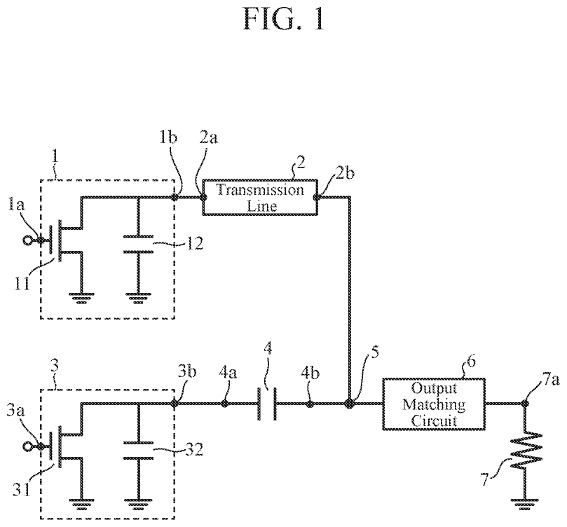

A Doherty amplifier according to Embodiment 1 will be explained on the basis of FIGS. 1 to 9.

In each of the figures, the same reference signs denote the same components or like components.

The Doherty amplifier according to Embodiment 1 includes a transistor 1 for main amplifier, a transmission line 2, a transistor 3 for auxiliary amplifier, a series capacitor 4, and an output matching circuit 6, as shown in FIG. 1.

In FIG. 1, because a parasitic capacitance 12 and a parasitic capacitance 32 are present in the transistor 1 for main amplifier and the transistor 3 for auxiliary amplifier, respectively, the parasitic capacitances are shown explicitly.

A signal amplified by the transistor 1 for main amplifier and a signal amplified by the transistor 3 for auxiliary amplifier are combined at a composite point 5 at the time of a saturated operation.

At the time of a backoff operation, the characteristic impedance Zc in an equivalent circuit extending from a current source 11 represented equivalently in the transistor 1 for main amplifier to the composite point 5 is expressed by the following equation (1).

$${Z}_{C} = ( √ {γ}_{1} \times Ropt ) / 2 > Ropt \qquad ( 1 )$$

In the equation (1), γ₁ is the ratio of the impedance (γ₁×Ropt/2) of an output load 8 disposed at the composite point 5 and the impedance (Ropt/2) of a load which is one-half of an optimal load Ropt, and can be defined as an impedance transformation ratio.

Hereinafter, for the sake of avoiding the complexity, the impedance Ropt of the optimal load is simply referred to as the optimal load Ropt.

Further, the impedance (γ₁×Ropt/2) of the output load 8 disposed at the composite point 5 is larger than the impedance (Ropt/2) which is one-half of the optimal load Ropt, and satisfies the following equation (2).

$${γ}_{1} \times Ropt / 2 > Ropt / 2 \qquad ( 2 )$$

The transistor 1 for main amplifier operates in class AB.

As the transistor 1 for main amplifier, a transistor such as a field effect transistor (FET), a heterojunction bipolar transistor (HBT), a high electron mobility transistor (HEMT), or a GaNHEMT using gallium nitride (GaN) is used.

The transistor 1 for main amplifier may include circuit configuration elements needed as an amplifier, such as a stabilization circuit connected to an input side thereof, and a bias circuit connected to an output side thereof.

The transistor 1 for main amplifier has a gate electrode which serves as an input end 1a to receive an input signal, a drain electrode which serves as an output end 1b to output an output signal amplified, and a source electrode connected to a ground node.

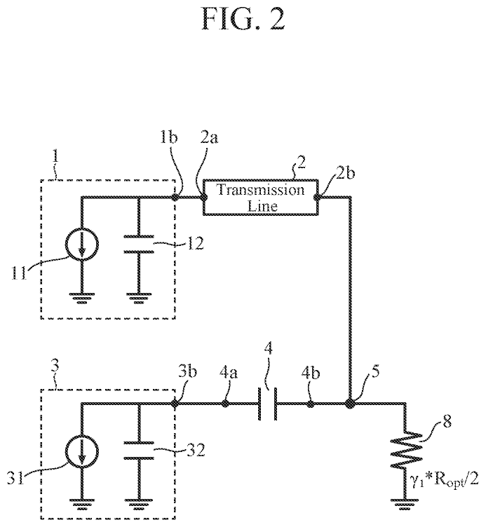

As shown in FIG. 1, the transistor 1 for main amplifier has the parasitic capacitance 12 having a capacitance value Cds and between the drain electrode and the source electrode (ground) of a transistor 11, and is assumed to be equivalently constituted by the current source 11 based on a current flowing between the drain electrode and the source electrode of the transistor, and the parasitic capacitance 12 having the capacitance value Cds between the drain electrode and the source electrode (ground) of the transistor, as shown in FIG. 2.

The transmission line 2 has an input end 2a which is connected to the output end 1b of the transistor 1 for main amplifier, and an output end 2b which is connected to the composite point 5.

The transistor 3 for auxiliary amplifier operates in class C.

As the transistor 3 for auxiliary amplifier, a transistor such as an FET, an HBT, a HEMT, or a GaNHEMT is used.

The transistor 3 for auxiliary amplifier may include circuit configuration elements needed as an amplifier, such as a stabilization circuit connected to an input side thereof, and a bias circuit connected to an output side thereof.

The transistor 3 for auxiliary amplifier has a gate electrode which serves as an input end 3a to receive an input signal, a drain electrode which serves as an output end 3b to output an output signal amplified, and a source electrode connected to a ground node.

As shown in FIG. 1, the transistor 3 for auxiliary amplifier has the parasitic capacitance 32 having a capacitance value Cds and inherent between the drain electrode and the source electrode (ground) of a transistor 31, and is assumed to be equivalently constituted by a current source 31 based on a current flowing between the drain electrode and the source electrode of the transistor, and the parasitic capacitance 32 having the capacitance value Cds between the drain electrode and the source electrode (ground) of the transistor, as shown in FIG. 2.

The series capacitor 4 has an input end 4a which is connected to the output end 3b of the transistor 3 for auxiliary amplifier, and an output end 4b which is connected to the composite point 5.

The series capacitor 4 reduces the composite capacitance value Ctotal of the impedance seen from the composite point 5 toward the output end 3b of the transistor 3 for auxiliary amplifier at the time of the backoff operation.

More specifically, the composite capacitance value Ctotal can be expressed by the following equation (3).

$$Ctotal = Cds \times ( Cs / ( Cds + C s ) ) \qquad ( 3 )$$

In the equation (3), Cds denotes the parasitic capacitance value between the drain electrode and the source electrode of the transistor 3 for auxiliary amplifier, and Cs denotes the capacitance value of the series capacitor 4.

It can be understood from the above equation (3) that when a virtual parallel inductor connected to the output end 4b of the series capacitor 4 and inherent in the output end 4b of the series capacitor 4, and the composite capacitance having the capacitance value Ctotal are combined, a component of the virtual parallel inductor remains in the impedance at the composite point 5 which appears at the time of the backoff operation because the composite capacitance value Ctotal is smaller than the parasitic capacitance value Cds of the transistor 3 for auxiliary amplifier. This remaining component of the virtual parallel inductor is referred to as the remaining parallel inductor component.

The output matching circuit 6 is connected between the composite point 5 and a point of connection 7a to an output load 7, and provides impedance matching between the characteristic impedance at the composite point 5 and the impedance of the output load 7.

As the output matching circuit 6, a circuit using a lumped constant element, a circuit using a distributed constant line, a circuit which is a combination of a lumped constant and a distributed constant, an LC matching circuit, or the like is used.

The impedance of the output load 7 is (γ₁×Ropt/2).

An output circuit of the Doherty amplifier according to Embodiment 1 has a simple configuration in which the source-to-drain parasitic capacitance 12 of the transistor for main amplifier is used at the time of the backoff operation, and the series capacitor 4 is disposed as a circuit element between the output end 3b of the transistor 3 for auxiliary amplifier and the composite point 5, and, as a result, constitutes a circuit having an F matrix equivalent to that of a transmission line whose characteristic impedance Zc is (√γ₁×Ropt)/2 larger than the optimal load Ropt of the transistor 1 for main amplifier, as expressed by the above equation (1), and whose electric length is shorter than 90 degrees, using the source-to-drain parasitic capacitance 12 of the transistor 1 for main amplifier, the transmission line 2, and a virtual parallel capacitor 101, as explained using the equivalent circuit diagrams shown in FIGS. 2 to 4.

The equivalent circuit of the Doherty amplifier according to the Embodiment 1 shown in FIG. 2 is expressed as the one in which in the circuit configuration diagram shown in FIG. 1, the transistor 1 for main amplifier is expressed with the current source 11 and the parasitic capacitance 12, the transistor 3 for auxiliary amplifier is expressed with the current source 31 and the parasitic capacitance 32, the output matching circuit 6 is omitted, and the output load 8 whose impedance is (γ₁×Ropt/2) is connected to the composite point 5.

The impedance (γ₁×Ropt/2) of the output load 8 is larger than the impedance (Ropt/2) which is one-half of the optimal load Ropt of the transistor 1 for main amplifier and the transistor 3 for auxiliary amplifier, as shown in the above equation (2).

Next, the principle of operation of the output circuit of the Doherty amplifier according to Embodiment 1 will be explained.

An explanation will be made with the principle of operation being divided into the one at the time of the backoff operation and the one at the time of the saturated operation, focusing on a symmetrical Doherty amplifier in which the transistor 1 for main amplifier and the transistor 3 for auxiliary amplifier have the same transistor size.

First, the principle of operation at the time of the backoff operation in the output circuit of the Doherty amplifier according to Embodiment 1 will be explained.

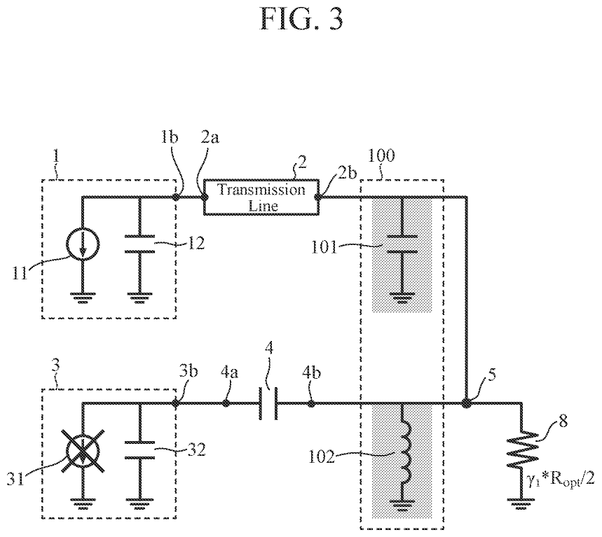

The output circuit of the Doherty amplifier according to Embodiment 1 can be transformed to an equivalent circuit which has a parallel capacitor 101 and a parallel inductor 102 which resonate with each other at the composite point 5, and in which the parallel capacitor 101 is disposed on the transistor-1-for-main-amplifier side, and the parallel inductor 102 is disposed on the transistor-3-for-auxiliary-amplifier side, as shown in FIG. 3.

The parallel capacitor 101 and the parallel inductor 102 are referred to as the virtual parallel capacitor 101 and the virtual parallel inductor 102, respectively.

More specifically, in the output circuit of the Doherty amplifier according to Embodiment 1, the virtual parallel capacitor 101 connected to the output end 2b of the transmission line 2 and the virtual parallel inductor 102 connected to the output end 4b of the series capacitor 4 and resonating with the virtual parallel capacitor 101 are included.

In FIG. 3, the virtual parallel capacitor 101 and the virtual parallel inductor 102 which resonate with each other are denoted by a broken line frame 100.

At the time of the backoff operation, because the transistor 3 for auxiliary amplifier does not operate, the current source 31 of the transistor 3 for auxiliary amplifier is open, as shown in FIG. 3.

The capacitance value Ctotal of the impedance seen from the composite point 5 toward the output end 3b of the transistor 3 for auxiliary amplifier is [Cds×(Cs/(Cds+Cs))], as shown in the above equation (3), and the composite capacitance value Ctotal is made by the series capacitor 4 to be smaller than the capacitance value Cds of the parasitic capacitance between the drain electrode and the source electrode of the transistor 3 for auxiliary amplifier.

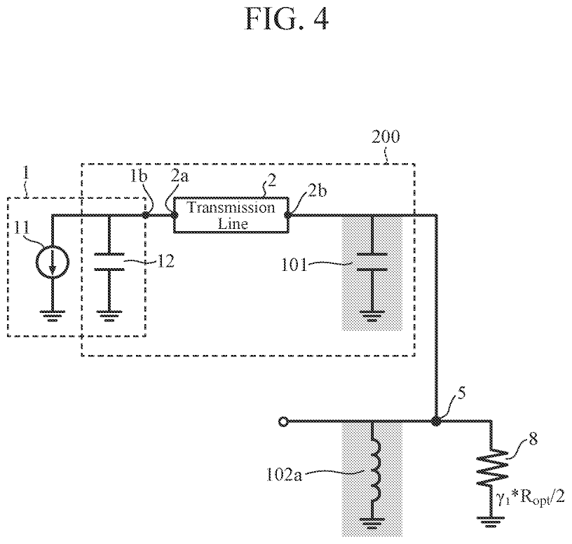

As a result, because the composite capacitance value Ctotal is smaller than the capacitance value Cds of the parasitic capacitance when the composite capacitance value Ctotal and the virtual parallel inductor 102 are combined, it can be transformed to an equivalent circuit in which a parallel inductor component 102a remains, as shown in FIG. 4.

This remaining parallel inductor component 102a is referred to as the remaining parallel inductor 102a.

In the equivalent circuit shown in FIG. 4, the source-to-drain parasitic capacitance 12 of the transistor 1 for main amplifier, the transmission line 2, and the virtual parallel capacitor 101 constitute a circuit 200 having an F matrix equivalent to that of a transmission line whose characteristic impedance Zc is expressed by the above equation (1) and is larger than the optimal load Ropt of the transistor 1 for main amplifier, and whose electric length is shorter than 90 degrees, the circuit 200 being denoted by a broken line frame 200 in FIG. 4.

Therefore, the impedance seen from the current source 11 equivalently representing the transistor 1 for main amplifier toward the composite point 5 can be transformed to high real impedance.

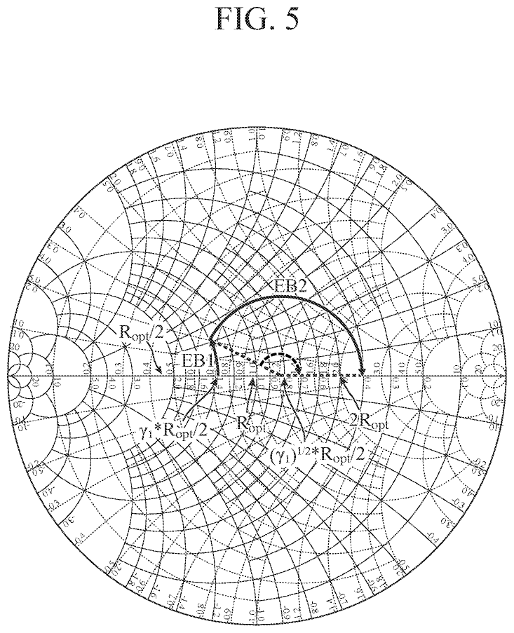

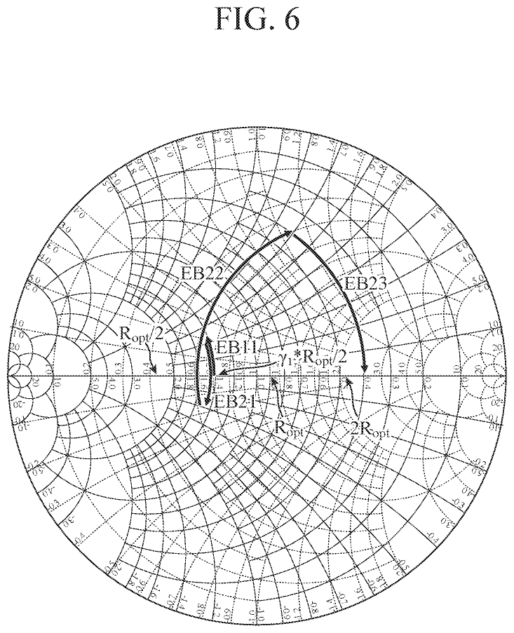

More specifically, the locus of the impedance transformation in a Smith chart at the time of the backoff operation is shown in FIGS. 5 and 6.

FIG. 5 is a view simply showing the locus of the impedance transformation from the composite point 5 to the current source 11 of the transistor 1 for main amplifier, and the impedance transformation is performed, starting from the impedance (γ₁×Ropt/2) of the output load, toward a direction in which the reflection coefficient is increased by the remaining parallel inductance 102a, as shown by a curve EB1. Next, the impedance transformation is performed by means of the circuit 200 having an F matrix equivalent to that of a transmission line whose electric length is shorter than 90 degrees, so that the impedance is transformed to impedance larger than the impedance (2×Ropt) which is twice as high as the optimal load Ropt of the transistor 1 for main amplifier, as shown by a curve EB2.

The characteristic impedance Zc of the equivalent circuit 200 is set to (√γ₁×Ropt)/2 expressed by the above equation (1).

In more detailed impedance transformation in the Smith chart at the time of the backoff operation, the impedance transformation is performed, starting from the impedance (γ₁×Ropt/2) of the output load, toward a direction in which the reflection coefficient is increased by the remaining parallel inductance 102a, shown by a curve EB11 shown in FIG. 6. The curve EB11 is the same as the curve EB1.

Next, via the locus of the impedance transformation shown by a curve EB21 and performed by the virtual parallel capacitor 101, the impedance transformation shown by a curve EB22 and performed by the transmission line 2, and the impedance transformation shown by a curve EB23 and performed by the parasitic capacitance 12 of the transistor 1 for main amplifier, the impedance is transformed to impedance larger than the impedance (2×Ropt) which is twice as high as the optimal load Ropt of the transistor 1 for main amplifier.

As is clear from the above explanation, it is possible to provide matching with impedance larger than the impedance (2×Ropt) which is twice as high as the optimal load Ropt of the transistor 1 for main amplifier at the time of the backoff operation in the output circuit of the Doherty amplifier according to Embodiment 1.

Next, the principle of operation at the time of the saturated operation in the output circuit of the Doherty amplifier according to Embodiment 1 will be explained.

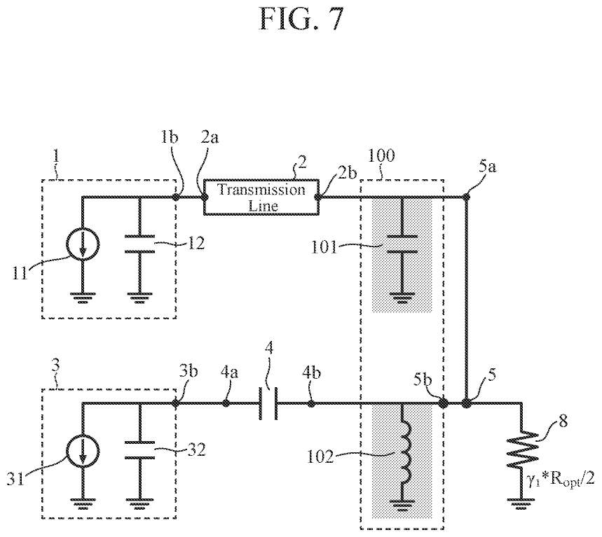

The output circuit of the Doherty amplifier according to Embodiment 1 can be transformed to an equivalent circuit which has the virtual parallel capacitor 101 and the virtual parallel inductor 102 which resonate with each other at the composite point 5, and in which the virtual parallel capacitor 101 is disposed on the transistor-1-for-main-amplifier side, and the virtual parallel inductor 102 is disposed on the transistor-3-for-auxiliary-amplifier side, like that at the time of the backoff operation, as shown in FIG. 7.

More specifically, in the output circuit of the Doherty amplifier according to Embodiment 1, the virtual parallel capacitor 101 connected to the output end 2b of the transmission line 2 and the virtual parallel inductor 102 connected to the output end 4b of the series capacitor 4 and resonating with the virtual parallel capacitor 101 are included.

In FIG. 7, the virtual parallel capacitor 101 and the virtual parallel inductor 102 which resonate with each other are denoted by a broken line frame 100.

At the time of the saturated operation, as shown in FIG. 7, currents having the same amplitude and the same phase flow through the composite point 5 because of a signal amplified by the transistor 1 for main amplifier and a signal amplified by the transistor 3 for auxiliary amplifier.

As a result, each of the following impedances: the impedance seen from a point 5a on the transistor-1-for-main-amplifier side which is the composite point 5, i.e. the output end 2b of the transmission line 2 toward the output side of the transistor 1 for main amplifier, and the impedance seen from a point 5b on the transistor-3-for-auxiliary-amplifier side which is the composite point 5, i.e. the output end 4b of the series capacitor 4 toward the output side of the transistor 3 for auxiliary amplifier becomes the impedance (γ₁×Ropt) which is twice as high as the impedance (γ₁×Ropt/2) of the output load 8.

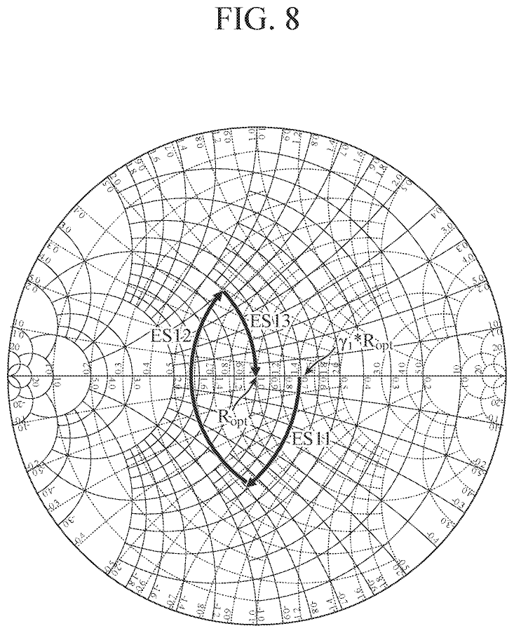

The locus of the impedance transformation from the point 5a (composite point 5) on the transistor-1-for-main-amplifier side to the current source 11 equivalently representing the transistor 1 for main amplifier in the Smith chart at the time of the saturated operation is shown in FIG. 8. The Smith chart of FIG. 8 is normalized to the optimal load Ropt.

Via the locus of the impedance transformation starting from the impedance (γ₁×Ropt) which is twice as high as the impedance (γ₁×Ropt/2) of the output load, and shown by a curve ES11 and performed by the virtual parallel capacitor 101, the impedance transformation shown by a curve ES12 and performed by the transmission line 2, and the impedance transformation shown by a curve ES13 and performed by the parasitic capacitance 12 of the transistor 1 for main amplifier, the impedance is transformed to the optimal load Ropt of the transistor 1 for main amplifier.

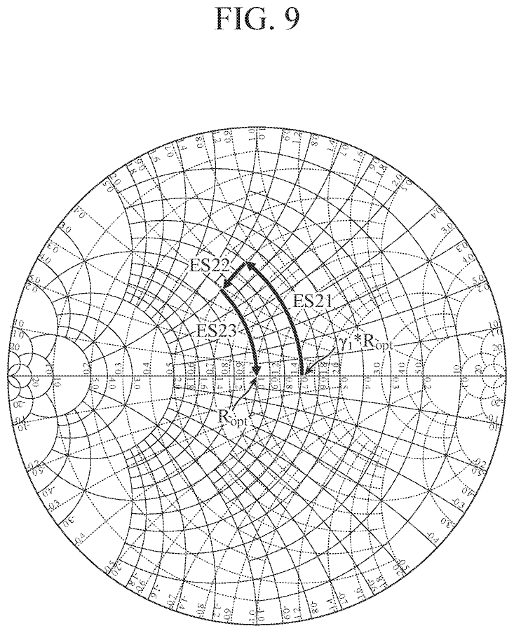

On the other hand, the locus of the impedance transformation from the point 5b (composite point 5) on the transistor-3-for-auxiliary-amplifier side to the current source 31 equivalently representing the transistor 3 for auxiliary amplifier in the Smith chart at the time of the saturated operation is shown in FIG. 9. The Smith chart of FIG. 9 is normalized to the optimal load (Ropt).

Via the locus of the impedance transformation shown by a curve ES21, starting from the impedance (γ₁×Ropt) which is twice as high as the impedance (γ₁×Ropt/2) of the output load, and performed by the virtual parallel inductor 102, the impedance transformation shown by a curve ES22 and performed by the series capacitor 4, and the impedance transformation shown by a curve ES23 and performed by the parasitic capacitance 32 of the transistor 3 for auxiliary amplifier, the impedance is transformed to the optimal load Ropt of the transistor 3 for auxiliary amplifier.

Therefore, even when the impedance (γ₁×Ropt/2) of the output load 8 connected to the composite point 5 is larger than the impedance (Ropt/2) which is one-half of the optimal load Ropt, both the impedance at the current source 11 of the transistor 1 for main amplifier and the impedance at the current source 31 of the transistor 3 for auxiliary amplifier are matched to the optimal load Ropt.

More specifically, the Doherty amplifier according to Embodiment 1 uses a signal having a large PAPR, increases the impedance of the output load at the time of the backoff operation in order to increase the backoff amount, thereby achieving a higher degree of efficiency, and causes impedance matching of both the impedance at the current source 11 of the transistor 1 for main amplifier and the impedance at the current source 31 of the transistor 3 for auxiliary amplifier to the optimal load Ropt of the transistor 1 for main amplifier and the transistor 3 for auxiliary amplifier to be satisfied at the time of the saturated operation, thereby providing maximum output power.

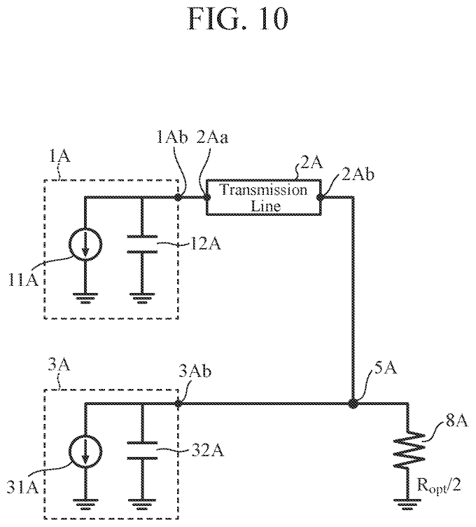

Hereinafter, a reference example 1 of a Doherty amplifier which is provided to make a comparison with the Doherty amplifier according to Embodiment 1 will be explained using FIGS. 10 to 16.

An equivalent circuit of an output circuit of the Doherty amplifier of the reference example 1 is assumed to be one which includes a transistor 1A for main amplifier represented by a current source 11A and a parasitic capacitance 12A, and a transistor 3A for auxiliary amplifier represented by a current source 31A and a parasitic capacitance 32A, and in which an output matching circuit is omitted, and an output load 8A having an impedance of (Ropt/2) is connected to a composite point 5A, as shown in FIG. 10.

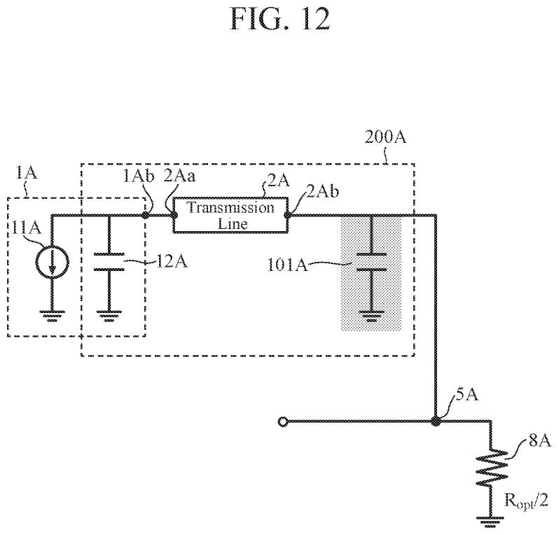

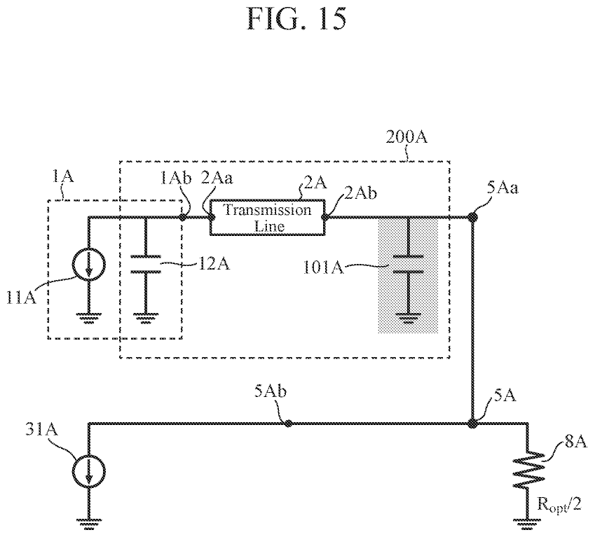

Further, a circuit shown in FIGS. 12 and 15 and denoted by a broken line frame 200A is a circuit 200A which is constituted by the source-to-drain parasitic capacitance 12A of the transistor 1A for main amplifier, a transmission line 2A, and a virtual parallel capacitor 101A, and which has an F matrix equivalent to that of a transmission line whose electric length is 90 degrees.

The equivalent circuit 200A is referred to as the equivalent 90-degree line 200A.

First, the principle of operation at the time of the backoff operation in the output circuit of the Doherty amplifier of the reference example 1 will be explained.

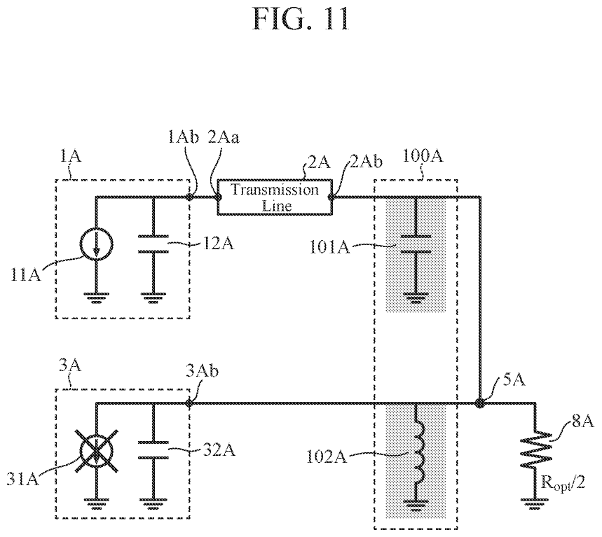

The output circuit of the Doherty amplifier of the reference example 1 can be transformed to an equivalent circuit which has a virtual parallel capacitor 101A and a virtual parallel inductor 102A which resonate with each other at the composite point 5A, and in which the virtual parallel capacitor 101A is disposed on the transistor-1A-for-main-amplifier side, and the virtual parallel inductor 102A is disposed on the transistor-3A-for-auxiliary-amplifier side, as shown in FIG. 11.

At the time of the backoff operation, the current source 31A of the transistor 3A for auxiliary amplifier is open because the transistor 3A for auxiliary amplifier does not operate, as shown in FIG. 11.

In a case where the virtual parallel inductor 102A and the parasitic capacitance 32A of the transistor 3A for auxiliary amplifier are set in such a way as to resonate with each other, it can be transformed to an equivalent circuit in which the transistor 3A for auxiliary amplifier is open as shown in FIG. 12.

Further, the circuit shown in FIG. 12 and denoted by the broken line frame 200A is an equivalent 90-degree line 200A.

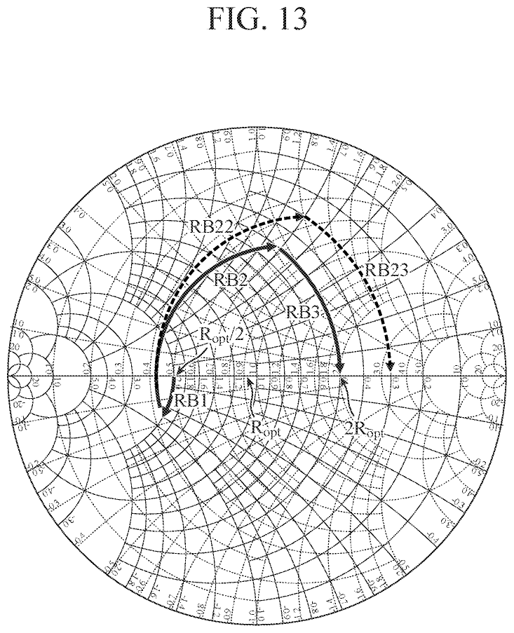

The locus of the impedance transformation from the composite point 5A to the current source 11A of the transistor 1A for main amplifier in the Smith chart at the time of the backoff operation is shown, in FIG. 13, by a solid line.

More specifically, via the locus of the impedance transformation starting from the impedance (Ropt/2) of the output load 8A, and shown by a curve RB1 and performed by the virtual parallel capacitor 101A, the impedance transformation shown by a curve RB2 and performed by the transmission line 2, and the impedance transformation shown by a curve RB3 and performed by the parasitic capacitance 12A of the transistor 1A for main amplifier, the impedance is transformed to the impedance (2×Ropt) which is twice as high as the optimal load Ropt of the transistor 1A for main amplifier.

Next, the principle of operation at the time of the saturated operation in the output circuit of the Doherty amplifier of the reference example 1 will be explained.

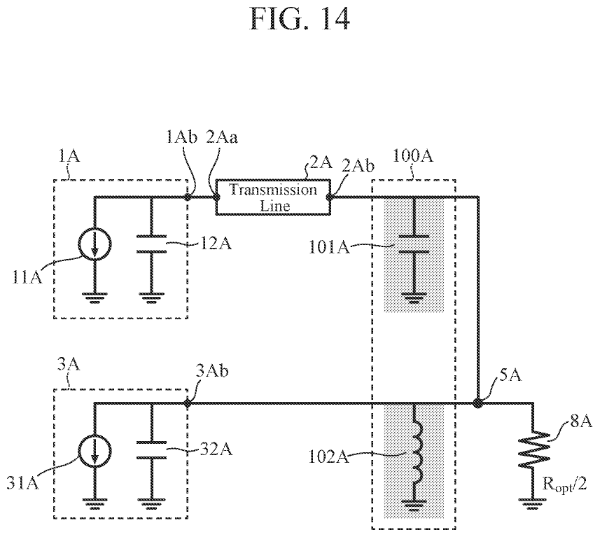

The output circuit of the Doherty amplifier of the reference example 1 can be transformed to an equivalent circuit which has a virtual parallel capacitor 101A and a virtual parallel inductor 102A which resonate with each other at the composite point 5A, and in which the virtual parallel capacitor 101A is disposed on the transistor-1A-for-main-amplifier side, and the virtual parallel inductor 102A is disposed on the transistor-3A-for-auxiliary-amplifier side, like that at the time of the backoff operation, as shown in FIG. 14.

At the time of the saturated operation, as shown in FIG. 14, currents having the same amplitude and the same phase flow through the composite point 5A because of a signal amplified by the transistor 1A for main amplifier and a signal amplified by the transistor 3A for auxiliary amplifier.

As a result, each of the following impedances: the impedance seen from a point 5Aa on the transistor-1A-for-main-amplifier side which is the composite point 5A, i.e. an output end 2Ab of the transmission line 2A toward the output side of the transistor 1A for main amplifier, and the impedance seen from a point 5Ab on the transistor-3A-for-auxiliary-amplifier side which is the composite point 5A toward the output side of the transistor 3A for auxiliary amplifier becomes the impedance Ropt which is twice as high as the impedance (Ropt/2) of the output load 8A.

At this time, because no circuit element is present between the current source 31A of the transistor 3A for auxiliary amplifier and the point 5Ab on the transistor-3A-for-auxiliary-amplifier side, the impedance seen from the current source 31A of the transistor 3A for auxiliary amplifier toward the output side remains at the optimal load Ropt just as it is.

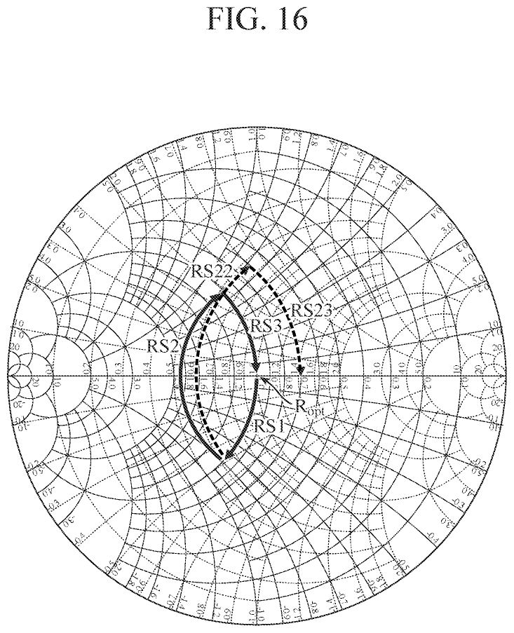

The locus of the impedance transformation from the composite point 5A to the current source 11A of the transistor 1A for main amplifier in the Smith chart at the time of the saturated operation is shown, in FIG. 16, by a solid line.

More specifically, via the locus of the impedance transformation starting from the impedance Ropt which is twice as high as the impedance (Ropt/2) of the output load 8A, and shown by a curve RS1 and performed by the virtual parallel capacitor 101A, the impedance transformation shown by a curve RS2 and performed by the transmission line 2A, and the impedance transformation shown by a curve RS3 and performed by the parasitic capacitance 12A of the transistor 1A for main amplifier, the impedance is transformed to the optimal load Ropt of the transistor 1A for main amplifier.

As mentioned above, by disposing the equivalent 90-degree line 200A on the transistor-1A-for-main-amplifier side in the output circuit of the Doherty amplifier of the reference example 1, when the output load 8A having an impedance (Ropt/2) is connected to the composite point 5A, transformation from the impedance (Ropt/2) of the output load 8A to the impedance (2×Ropt) which is twice as high as the optimal load Ropt is made at the time of the backoff operation, to make the impedance at the current source 11A of the transistor 1A for main amplifier to be the one (2×Ropt) which is twice as high as the optimal load Ropt, so that high efficiency can be achieved. Further, at the time of the saturated operation, transformation from the optimal load Ropt of the transistor 1A for main amplifier to the optimal load Ropt is made in the transistor 1A for main amplifier, and the impedance at the current source 11A of the transistor 1A for main amplifier is made to be the optimal load Ropt which is the same as the impedance at the current source 31A of the transistor 3A for auxiliary amplifier, so that impedance matching is satisfied.

Another reference example is assumed to have a configuration in which in the output circuit of the Doherty amplifier of the reference example 1, in order to further improve the efficiency at the time of the backoff operation, the characteristic impedance and the electric length of the transmission line 2A are adjusted to increase the characteristic impedance of the equivalent 90-degree line so that an output load having an impedance of (γ₁×Ropt/2) can be connected to the composite point 5A, like the output circuit of the Doherty amplifier according to Embodiment 1. This assumed reference example is referred to as the Doherty amplifier of a reference example 2.

In the output circuit of the Doherty amplifier of the reference example 2, the locus of the impedance transformation from the composite point 5A to the current source 11A of the transistor 1A for main amplifier in the Smith chart at the time of the backoff operation is shown in FIG. 13 and denoted by a broken line.

More specifically, via the locus of the impedance transformation starting from the impedance (Ropt/2) of the output load 8A, and shown by a curve RB1 and performed by the virtual parallel capacitor 101A, the impedance transformation shown by a curve RB22 and performed by the transmission line 2A, and the impedance transformation shown by a curve RB23 and performed by the parasitic capacitance 12A of the transistor 1A for main amplifier, the impedance is transformed to impedance larger than the impedance (2×Ropt) which is twice as high as the optimal load Ropt of the transistor 1A for main amplifier.

Further, the locus of the impedance transformation from the composite point 5A to the current source 11A of the transistor 1A for main amplifier in the Smith chart at the time of the saturated operation is shown, in FIG. 16, by a broken line.

More specifically, via the locus of the impedance transformation starting from the impedance Ropt which is twice as high as the impedance (Ropt/2) of the output load 8A, and shown by a curve RS1 and performed by the virtual parallel capacitor 101A, the impedance transformation shown by a curve RS22 and performed by the transmission line 2A, and the impedance transformation shown by a curve RS23 and performed by the parasitic capacitance 12A of the transistor 1A for main amplifier, the impedance is transformed to impedance larger than the optimal load Ropt of the transistor 1A for main amplifier.

Therefore, when the impedance (γ₁×Ropt/2) of the output load 8A connected to the composite point 5A is larger than the impedance (Ropt/2) which is one-half of the optimal load Ropt in the output circuit of the Doherty amplifier of the reference example 2, impedance matching cannot be provided for the impedance at the current source 11A of the transistor 1A for main amplifier at the time of the saturated operation, unlike for the impedance at the current source 31A of the transistor 3A for auxiliary amplifier.

As a result, in the Doherty amplifier of the reference example 2, maximum output power is not acquired at the time of the saturated operation.

To sum up, in the output circuits of the Doherty amplifiers shown as the reference examples, because the impedance seen from the current source 31A of the transistor 3A for auxiliary amplifier toward the output side is twice as high as the impedance of the output load 8A at the time of the saturated operation, it is indispensable to make the output load 8A connected to the composite point 5A be one-half of the optimal load Ropt in order to match both the impedance at the current source 11A of the transistor 1A for main amplifier and the impedance at the current source 31A of the transistor 3A for auxiliary amplifier to the optimal load Ropt.

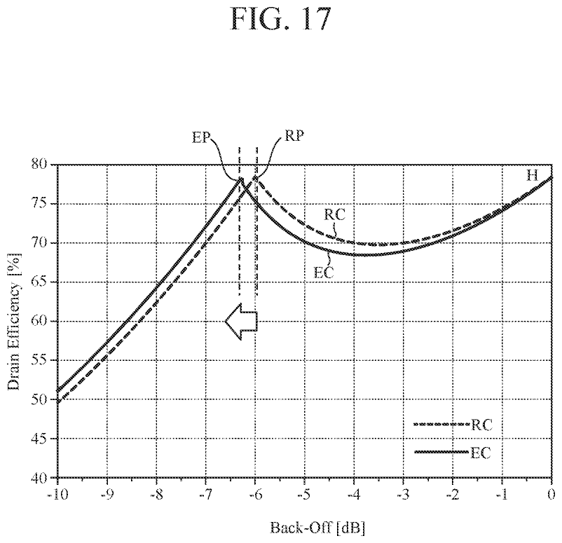

Specific examples of the computation of the drain efficiency of the transistors 1 and 1A for main amplifier with respect to the backoff amount at the time of the backoff operation, for both the Doherty amplifier according to Embodiment 1 and the Doherty amplifier of the reference example 1, are shown in FIG. 17.

In FIG. 17, the horizontal axis shows the backoff amount from a saturated output power point, the vertical axis shows the drain efficiency, a solid line EC shows a characteristic curve for the Doherty amplifier according to Embodiment 1, and a broken line RC shows a characteristic curve for the Doherty amplifier of the reference example 1.

The saturated output power point is a power point where at the time of the saturated operation, the impedance at the current source 11 or 11A of the transistor 1 or 1A for main amplifier and the impedance at the current source 31 or 31A of the transistor 3 or 3A for auxiliary amplifier satisfy impedance matching with the optimal load Ropt of the transistor 1 or 1A for main amplifier and the transistor 3 or 3A for auxiliary amplifier, and where the maximum output power is acquired.

As shown in FIG. 17, in the Doherty amplifier according to Embodiment 1, an efficiency peak EP appears at a point which backs off the saturated output power point, while in the Doherty amplifier of the reference example 1, an efficiency peak RP appears at the saturated output power point.

The backoff point where the efficiency peak EP in the Doherty amplifier according to Embodiment 1 appears is larger than the backoff point where the efficiency peak RP in the Doherty amplifier of the reference example 1 appears.

Because the larger the backoff point is, the higher-efficient amplification is performed on the signal having a large PAPR, the Doherty amplifier according to Embodiment 1 can implement amplification having higher efficiency than that of the Doherty amplifier of the reference example 1 on the signal having a large PAPR.

As mentioned above, in the Doherty amplifier according to Embodiment 1, because the transistor 1 for main amplifier operating in class AB and the transistor 3 for auxiliary amplifier operating in class C are connected in parallel, the parasitic capacitance of the transistor 1 for main amplifier and the parasitic capacitance of the transistor 3 for auxiliary amplifier are used, the input end 4a is connected to the output end 3b of the transistor 3 for auxiliary amplifier, the output end 4b is connected to the composite point 5, and the series capacitor 4 to reduce the capacitance value of the impedance seen from the composite point 5 toward the output end 3b of the transistor 3 for auxiliary amplifier at the time of the backoff operation is disposed, while the Doherty amplifier can satisfy matching between the impedance at the current source 11 of the transistor 1 for main amplifier and the impedance at the current source 31 of the transistor 3 for auxiliary amplifier at the time of the saturated operation, the Doherty amplifier can increase the backoff amount at which an efficiency peak point appears and implement high-efficiency amplification on a signal having a large PAPR at the time of the backoff operation.

Further, in the Doherty amplifier according to Embodiment 1, because the transistor 1 for main amplifier operating in class AB and the transistor 3 for auxiliary amplifier operating in class C are connected in parallel, the parasitic capacitance of the transistor 1 for main amplifier and the parasitic capacitance of the transistor 3 for auxiliary amplifier are used, the virtual parallel capacitor 101 connected to the output end 2b of the transmission line 2 and the virtual parallel inductor 102 connected to the output end 4b of the series capacitor 4 and resonating with the virtual parallel capacitor 101 are included, and at the time of the backoff operation, the source-to-drain parasitic capacitance 12 of the transistor 1 for main amplifier, the transmission line 2, and the virtual parallel capacitor 101 constitute the circuit 200 having an F matrix equivalent to that of a transmission line whose characteristic impedance is larger than the impedance Ropt of the optimal load of the transistor 1 for main amplifier and whose electric length is shorter than 90 degrees, while the Doherty amplifier can satisfy matching between the impedance at the current source 11 of the transistor 1 for main amplifier and the impedance at the current source 31 of the transistor 3 for auxiliary amplifier at the time of the saturated operation, the Doherty amplifier can increase the backoff amount at which an efficiency peak point appears and implement high-efficiency amplification on a signal having a large PAPR at the time of the backoff operation.

### Embodiment 2

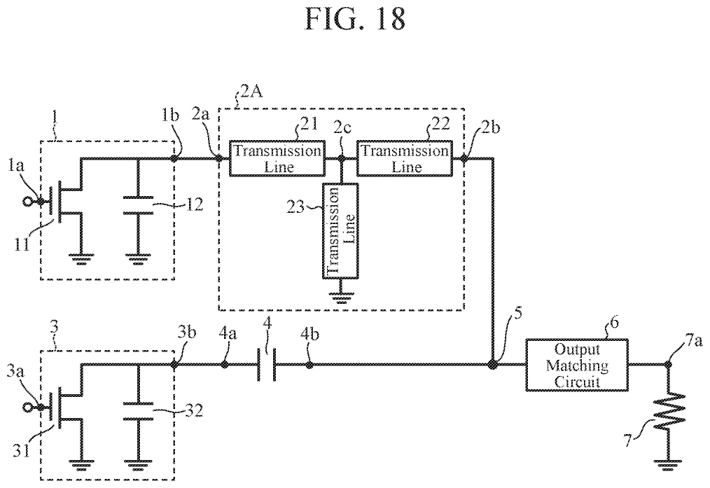

A Doherty amplifier according to Embodiment 2 will be explained on the basis of FIG. 18.

The Doherty amplifier according to Embodiment 2 differs from the Doherty amplifier according to Embodiment 1 in that there is provided, instead of the transmission line 2, a transmission line 2A constituted by a T-type circuit including: a first serial transmission line 21 whose end is connected to an input end 2a; a second serial transmission line 22 whose end is connected to the first serial transmission line 21 and whose other end is connected to an output end 2b; and a parallel transmission line 23 whose end is connected to a point of connection 2C between the first serial transmission line 21 and the second serial transmission line 22 and whose other end is short-circuited at high frequencies, and is the same as the Doherty amplifier according to Embodiment 1 in other components.

In the transmission line 2A constituted by the T-type circuit, a DC-blocking capacitor connected to the parallel transmission line 23 is omitted.

In FIG. 18, the same reference signs as those in FIG. 1 denote the same components or like components.

The F matrix of the transmission line 2A constituted by the T-type circuit in the Doherty amplifier according to Embodiment 2 adjusts the characteristic impedance and the electric length of the transmission line 2A, and is the same as the F matrix of the transmission line 2 in the Doherty amplifier according to Embodiment 1.

As a result, while the Doherty amplifier according to Embodiment 2 satisfies matching between the impedance at the current source 11 of a transistor 1 for main amplifier and the impedance at the current source 31 of a transistor 3 for auxiliary amplifier at the time of a saturated operation, the Doherty amplifier can increase the backoff amount at which an efficiency peak point appears and implement high-efficiency amplification on a signal having a large PAPR at the time of a backoff operation, like the Doherty amplifier according to Embodiment 1.

It is to be understood that an arbitrary combination of embodiments can be made, a change can be made in an arbitrary component of each of the embodiments, or an arbitrary component in each of the embodiments can be omitted.

### INDUSTRIAL APPLICABILITY

The Doherty amplifier according to the present disclosure is suitable as a Doherty amplifier in which a transistor for main amplifier operating, as a carrier amplifier, in class AB, and a transistor for auxiliary amplifier operating, as a peak amplifier, in class C are connected in parallel.

Particularly, the Doherty amplifier according to the present disclosure is suitable as a Doherty amplifier used for wireless communication systems like those for mobile phones.

### REFERENCE SIGNS LIST

1: Transistor for main amplifier, 2 and 2A: Transmission line, 21: First serial transmission line, 22: Second serial transmission line, 23: Parallel transmission line, 3: Transistor for auxiliary amplifier, 4: Series capacitor, 5: Composite point, 6: Output matching circuit, 7 and 8: Output load, 101: Virtual parallel capacitor, and 102: Virtual parallel inductor.

What is claimed is:

1. A Doherty amplifier comprising:
a transistor for main amplifier having a source-to-drain parasitic capacitance and operating in class AB;
a transmission line whose input end is connected to an output end of the transistor for main amplifier and whose output end is connected to a composite point;
a transistor for auxiliary amplifier having a source-to-drain parasitic capacitance and operating in class C;
a series capacitor whose input end is connected to an output end of the transistor for auxiliary amplifier and whose output end is connected to the composite point, and to reduce a capacitance value of impedance seen from the composite point toward the output end of the transistor for auxiliary amplifier at a time of a backoff operation; and
an output matching circuit connected between the composite point and a point of connection to an output load, and to match impedance at the composite point to impedance of the output load.

2. A Doherty amplifier comprising:
a transistor for main amplifier having a source-to-drain parasitic capacitance and operating in class AB;
a transmission line whose input end is connected to an output end of the transistor for main amplifier and whose output end is connected to a composite point;
a transistor for auxiliary amplifier having a source-to-drain parasitic capacitance and operating in class C;
a series capacitor whose input end is connected to an output end of the transistor for auxiliary amplifier and whose output end is connected to the composite point; and
an output matching circuit connected between the composite point and a point of connection to an output load, and to match impedance of the composite point to impedance of the output load,
wherein a virtual parallel capacitor connected to the output end of the transmission line and a virtual parallel inductor connected to the output end of the series capacitor and resonating with the virtual parallel capacitor are inherent in the Doherty amplifier, and at a time of a backoff operation, the source-to-drain parasitic capacitance of the transistor for main amplifier, the transmission line, and the virtual parallel capacitor constitute a transmission line having an F matrix equivalent to that of a transmission line whose characteristic impedance is larger than impedance of an optimal load of the transistor for main amplifier and whose electric length is shorter than 90 degrees.

3. The Doherty amplifier according to claim 1, wherein the transmission line is a T-type circuit having a first serial transmission line whose end is connected to the input end thereof, a second serial transmission line whose first end is connected to the first serial transmission line and whose second end is connected to the output end thereof, and a parallel transmission line whose first end is connected to a point of connection between the first serial transmission line and the second serial transmission line and whose second end is short-circuited at high frequencies.

4. The Doherty amplifier according to claim 2, wherein the transmission line is a T-type circuit having a first serial transmission line whose end is connected to the input end thereof, a second serial transmission line whose first end is connected to the first serial transmission line and whose second end is connected to the output end thereof, and a parallel transmission line whose first end is connected to a point of connection between the first serial transmission line and the second serial transmission line and whose second end is short-circuited at high frequencies.
